(19) United States
(12) Patent Application Publication
(10) Pub. No.: US 2026/0250836 A1
(43) Pub. Date: Aug. 27, 2026

(54) METHOD FOR SELECTIVELY DEPOSITING SILICON OXIDE LAYER USING AMINOSILANE PRECURSOR

(71) Applicants: SK SPECIALTY CO., LTD., Yeongju-si, Gyeongsangbuk-do (KR); INDUSTRY-UNIVERSITY COOPERATION FOUNDATION HANYANG UNIVERSITY ERICA CAMPUS, Ansan-si, Gyeonggi-do (KR)

(72) Inventors: Sung Woong CHUNG, Sejong (KR); Jung Hun KWAK, Sejong (KR); Ji Hun LEE, Sejong (KR); Woo Hee KIM, Ansan-si, Gyeonggi-do (KR); Jeong Min LEE, Ansan-si, Gyeonggi-do (KR); Seo Hyun LEE, Ansan-si, Gyeonggi-do (KR)

(73) Assignees: SK SPECIALTY CO., LTD., Yeongju-si, Gyeongsangbuk-do (KR); INDUSTRY-UNIVERSITY COOPERATION FOUNDATION HANYANG UNIVERSITY ERICA CAMPUS, Ansan-si, Gyeonggi-do (KR)

(21) Appl. No.: 18/870,711

(22) PCT Filed: Jun. 15, 2023
(86) PCT No.: PCT/KR2023/008300

§ 371 Date: Dec. 2, 2024

(30) Foreign Application Priority Data
Jun. 17, 2022 (KR) 10-2022-0073907

(51) Int. Cl. C23C 16/04; C23C 16/02; C23C 16/40; C23C 16/455; H10P 14/60; H10P 14/692

(52) U.S. Cl. CPC C23C 16/04; C23C 16/0227; C23C 16/401; C23C 16/45553; H10P 14/6339; H10P 14/6682; H10P 14/69215

(57) ABSTRACT

A method for selectively depositing a silicon oxide layer using an aminosilane precursor, includes: a preparation step of preparing, in a vacuum chamber, a substrate on which a first silicon oxide (SiO2) layer and a titanium nitride (TiN) layer are exposed; a first supply step of supplying an aminosilane-based gas to the vacuum chamber so as to be adsorbed on at least the first silicon oxide layer; and a second supply step of supplying an oxidizing agent to the vacuum chamber so as to react with the adsorbed aminosilane-based gas. The first supply step and the second supply step are repeatedly performed a plurality of times, thereby forming a second silicon oxide layer having a predetermined thickness on the first silicon oxide layer.

### CROSS-REFERENCE TO PRIOR APPLICATIONS

This Application is a National Stage Patent Application of PCT International Application No. PCT/KR2023/008300 (filed on Jun. 15, 2023), which claims priority to Korean Patent Application No. 10-2022-0073907 (filed on Jun. 17, 2022), which are all hereby incorporated by reference in their entirety.

### BACKGROUND

The present invention relates to a semiconductor deposition process, and more particularly, to a method of selectively depositing a silicon oxide layer only in a specific region on a substrate using an aminosilane-based precursor.

As the ultra-miniaturization of semiconductor devices continues to proceed, the semiconductor fabrication process is more complex and stringent. Accordingly, in the case of an existing top-down patterning process based on optical lithography, problems such as non-uniformity of alignment due to the reduction of a critical dimension (CD) pattern, an increase in roughness of a pattern surface (for example, Line Edge Roughness (LER), Line Width Roughness (LWR), and the like) have become a key issue.

To solve this problem, a region selective deposition process has been proposed. The region selective deposition process refers to a deposition process in which deposition is performed in a specific region on a substrate, but deposition is not performed in other regions around the deposition process.

One of the region selective deposition processes is to form a cover layer covering an region where deposition is not desired on a substrate, and then perform deposition on the entire area of the substrate. For example, a method of performing deposition after forming a cover layer of an ultra-fine pattern only on a partial region of a substrate using a self-assembled monolayer-based inhibitor is known. Accordingly, after the deposition is completed, the deposition layer on the upper side is removed together with the cover layer by ashing or etching, so that the deposition layer (pattern) may remain only in the region of the substrate on which the cover layer is not formed. However, since this requires a cover layer formation using an inhibitor and an additional process for removing the cover layer, there is a disadvantage in that the process is complicated and the time required for the deposition process is increased. In addition, in a deposition process, when a plasma enhanced atomic layer deposition (PEALD) process using direct plasma is applied, damage to a recess pattern or a lower layer caused by plasma during a process is problematic.

As a region selective deposition process for solving the aforementioned disadvantages, a selective deposition process using inherent selectivity properties of materials is known. This allows deposition only on the surface of some of the plurality of surfaces of different materials on the substrate, using the unique properties of the material, such as the relative properties of affinity or adhesion to a particular material. In this case, deposition is not performed on the surface of another material or a predetermined reaction is induced. For example, in Korean Patent Laid-Open Publication No. 2018-0111537, “Selective Growth Method” (Patent Document 1), a process of sequentially supplying an aminosilane-based gas having a hydrocarbon group and a reaction gas is repeatedly performed several times in an object to be treated having a lower limb in which an insulating layer and a conductive layer are exposed, A method of selectively growing a silicon-based insulating layer only on an insulating layer and simultaneously vaporizing the conductive layer to reduce a film is disclosed.

### PRIOR ART

(Patent Document 1) Korean Patent Laid-Open Publication No. 2018-0111537

### SUMMARY

In the fabrication of a next-generation dynamic random access memory (DRAM) device having an ultra-fine pattern, when a storage node of a DRAM is formed using a photolithography and etching process, issues such as line width non-uniformity and/or narrow pillars collapsing or bending may occur. When a silicon oxide layer is formed by supplying a silicon source gas through an ALD process using direct plasma, damage to the exposed metal layer may be easily caused.

Therefore, by using the intrinsic selective properties of the materials for the substrate in which the titanium nitride layer and the silicon oxide layer are simultaneously exposed, the silicon oxide layer is deposited only on the silicon oxide layer without damaging the titanium nitride layer. In particular, in the fabrication of a DRAM device having a capacitor node in which a silicon oxide layer is exposed together with at least a titanium nitride layer, a process is required that selectively deposits a silicon oxide layer only on the sidewall of a pillar formed of a silicon oxide layer, without damaging the titanium nitride layer.

An object of the present invention is to provide a selective deposition method of a silicon oxide layer using an aminosilane-based precursor capable of selectively depositing a silicon oxide layer only on a silicon oxide layer without damaging the titanium nitride layer with respect to a semiconductor substrate in which a titanium nitride layer and a silicon oxide layer are exposed.

According to an aspect of the present embodiment, there is provided a method of selectively depositing silicon oxide, the method including preparing a substrate in which a first silicon oxide layer and a titanium nitride layer are exposed in a vacuum chamber, supplying an aminosilane-based gas to the vacuum chamber to be adsorbed on at least the first silicon oxide layer, and supplying an oxidizing agent to the vacuum chamber so as to react with the adsorbed aminosilane-based gas, The first supply operation and the second supply operation are repeatedly performed a plurality of times to form a second silicon oxide layer having a predetermined thickness on the first silicon oxide layer.

According to an aspect of the present embodiment, the aminosilane-based gas may include at least one of BDIPADS, DIPAS, and 3 DMAS.

According to another aspect of the present embodiment, the oxidizing agent may include one or more selected from ozone gas, oxygen gas, and a mixed gas of oxygen and hydrogen.

According to still another aspect of the present embodiment, the method may further include a pre-treatment step of cleaning the substrate with a hydrofluoric acid solution before the first supply step.

The temperature of the vacuum chamber may be set to 100 to 200° C. in the first supply step and the second supply step.

According to the above-described embodiment of the present invention, when the silicon oxide layer and the titanium nitride layer are simultaneously exposed, since the aminosilane-based gas is selectively adsorbed only to the silicon oxide layer and either not adsorbed to the titanium nitride layer or only a small amount of the aminosilane-based gas is adsorbed, silicon oxide may be selectively deposited only on the silicon oxide layer without adding an additional process to remove the inhibitor after its use.

### BRIEF DESCRIPTION OF THE DRAWINGS

FIG. 1 is a flowchart illustrating an example of a selective deposition method of a silicon oxide layer according to one embodiment of the present invention.

FIGS. 2a to 2c are cross-sectional views schematically illustrating a state in which each process of the selective deposition method illustrated in FIG. 1 is performed.

FIG. 3 is a graph showing a result of measuring a water contact angle with respect to a material layer on a substrate on which a predetermined treatment is performed.

FIG. 4 is a graph showing a deposition rate of a silicon oxide layer according to a temperature of an ALD process.

FIG. 5 is an ion milling transmission electron micrograph showing a result of performing selective deposition of a silicon oxide layer using an ALD rinsing process according to an embodiment of the present invention, wherein the temperature inside the vacuum chamber is set to 200° C.

FIG. 6 is an ion milling transmission electron micrograph showing a result of performing selective deposition of a silicon oxide layer using an ALD rinsing process according to an embodiment of the present invention, wherein the temperature inside the vacuum chamber is set to 100° C.

FIG. 7 is an ion milling transmission electron micrograph showing a result of performing selective deposition of a silicon oxide layer using an ALD rinsing process according to an embodiment of the present invention, wherein the temperature inside the vacuum chamber is set to 150° C.

### DETAILED DESCRIPTION

Hereinafter, embodiments of the present invention will be described in detail with reference to the accompanying drawings. The terms and words used in the present specification are terms selected in consideration of the functions in the embodiment, and the meaning of the term may vary depending on the intention or practice of the invention. Therefore, the terms used in the following embodiments follow the definition when specifically defined in the specification, and when a specific definition is not otherwise provided, they should be interpreted as having meanings that are generally recognized by those skilled in the art.

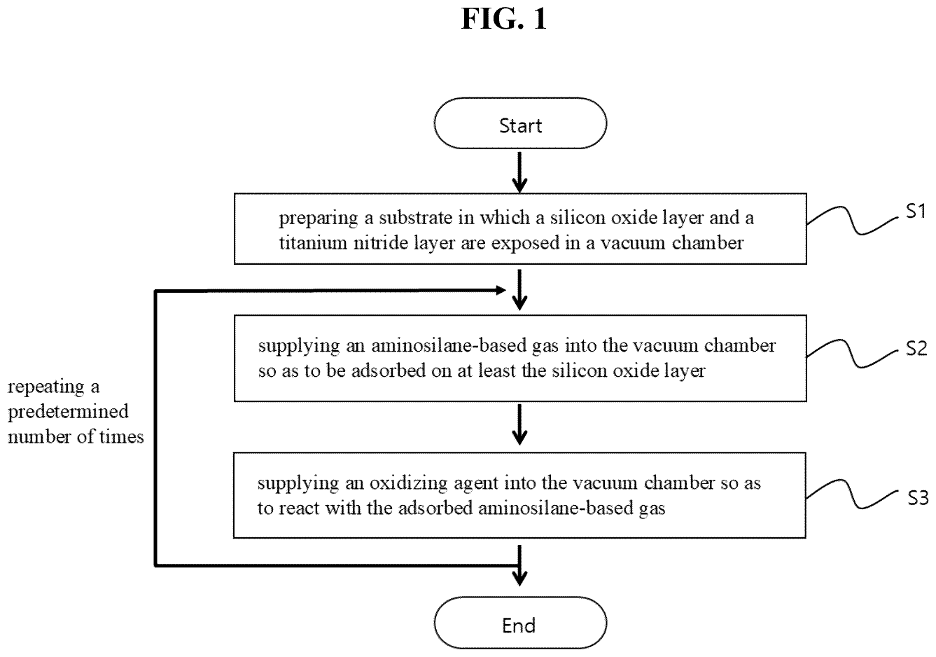

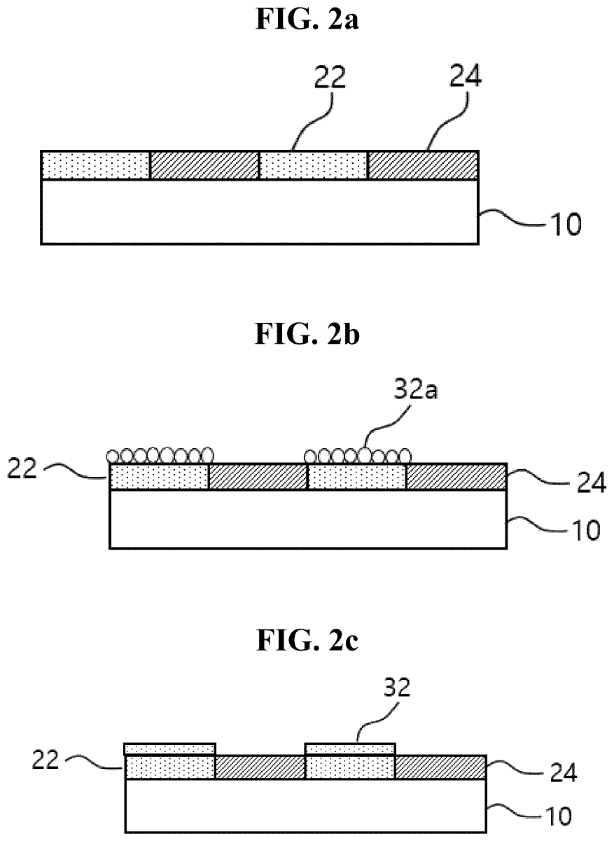

FIG. 1 is a flow chart illustrating an example of a selective deposition method of a silicon oxide layer according to an embodiment of the present invention, and FIGS. 2A to 2C are cross-sectional views schematically illustrating states when each process of the selective deposition method illustrated in FIG. 1 is performed.

Referring to FIGS. 1 and 2a, an object to be processed, in which a silicon oxide layer 22 (a first silicon oxide layer) and a titanium nitride layer 24 are formed on a substrate 10, is loaded into a vacuum chamber (step S1). For subsequent deposition processes, at least the silicon oxide layer 22 and the titanium nitride layer 24 are exposed to the upper side of the object to be treated. This object to be processed is schematically modeled after a structure used in semiconductor devices, such as those in DRAM manufacturing. The exposed surface of the silicon oxide layer 22 and the titanium nitride layer 24 is a surface to be treated, and a thin layer (silicon oxide layer) is selectively deposited thereon.

Here, the substrate 10 may be a semiconductor wafer, for example, a silicon wafer, but is not limited thereto. The silicon oxide layer 22 and the titanium nitride layer 24 need not be formed directly on the substrate 10, and one or more other material layers may be interposed between the silicon oxide layer 22 and the titanium nitride layer 24. The material layer may be an insulating layer and/or a conductive layer, and the type thereof is not particularly limited. According to the embodiment, at least one silicon oxide layer and/or a titanium nitride layer may be additionally interposed.

Furthermore, the height of the silicon oxide layer 22 and the titanium nitride layer 24 is not necessarily the same as shown in the drawing, and any one film (e.g. the titanium nitride layer 24) is higher than the other film (e.g. the silicon oxide layer 22). Also, as shown in the drawing, it is not necessary for the silicon oxide layer 22 and the titanium nitride layer 24 to be alternately formed on the substrate 10; another material layer (e.g., a conductive layer such as tungsten (W), copper (Cu), or cobalt (Co), and/or an insulating layer such as a silicon nitride layer (Si3N4)) may be interposed between the adjacent silicon oxide layer 22 and the titanium nitride layer 24.

According to an aspect of the present embodiment, before the object to be processed is loaded into the vacuum chamber, a process of preprocessing the object to be processed may be additionally performed. The pre-treatment process is a process of removing impurities attached to the surface of the object to be processed, particularly, the silicon oxide layer 22 and the titanium nitride layer 24, and removing the native oxide film present on the surface of the substrate to secure a surface functional group of each substrate. More specifically, the object to be treated is cleaned with a cleaning solution, such as a hydrofluoric acid (HF) solution, and then, a rinsing process and a drying process may be sequentially performed (for example, by using a 0.5 wt % HF solution for 30 seconds). Here, purified water may be used in the rinsing process, and nitrogen gas or similar gases may be used in the drying process, as an example.

Subsequently, referring to FIGS. 1 and 2b, a silicon precursor 32a is supplied into a vacuum chamber to be adsorbed on at least the silicon oxide layer 22 (S2). At this time, the silicon precursor 32a is not adsorbed at all on the titanium nitride layer 24, or even if it is adsorbed, a relatively small amount of the silicon precursor 32a is adsorbed. According to an embodiment, during the overall cycle of the atomic layer deposition process, the silicon precursor 32a may not be adsorbed on the titanium nitride layer 24, and the silicon precursor 32a may also be adsorbed on the titanium nitride layer 24 after a predetermined number of cycles.

According to the present embodiment, the selective adsorption of the silicon precursor 32a uses intrinsic selective characteristics of the corresponding material, and the silicon precursor 32a is adsorbed only to the silicon oxide layer 22, or is adsorbed to a greater extent on the silicon oxide layer 22 than on the titanium nitride layer 24 under the same process conditions. (e.g. a temperature in the process chamber, a pressure, and a flow rate of the silicon precursor gas). Therefore, the silicon precursor 32a may not need to be activated into a plasma and supplied to the vacuum chamber, and may be supplied to a vacuum chamber set to a temperature of relatively low temperature, about 50 to 300° C. preferably about 100 to 200° C. In this case, the process temperature may vary depending on the type of precursor used in a subsequent thin layer deposition process.

An aminosilane-based compound may be used as the silicon precursor 32a. The aminosilane-based compound has a characteristic of being easily adsorbed on the surface of the silicon oxide layer 22 having an-OH functional group rather than the surface of the titanium nitride layer 24 having no-OH functional group at the end thereof. As will be described later, when an atomic layer deposition (ALD) process is performed using an aminosilane-based compound, a silicon oxide layer having a thickness of about 4 nm to about 5 nm is grown on the silicon oxide layer 22, but a silicon oxide layer is not grown on the surface of the titanium nitride layer 24, according to experimental results by the present inventors. According to the present embodiment, the type of the aminosilane-based compound is not particularly limited, and may be, for example, 1,2-bisdiisopropylaminodisilane (BDIPADS), diisopropylaminosilane (DIPAS), or tri-dimethylaminosilane (3 DMAS). However, the type of the aminosilane-based compound is not limited thereto, and trimethylsilyldimethylamine (TMSDMA), tetrakis dimethylaminosilane (4 DMAS), or the like may be used.

In step S2, the vacuum chamber to which the silicon precursor 32a is supplied may be set to a vacuum pressure of about 2 Torr or less. As described above, the internal temperature of the vacuum chamber may be set to a temperature of about 50° C. to about 300° C., preferably about 100° C. to about 200° C. The silicon precursor 32a may be supplied to the vacuum chamber alone in a gaseous state by evaporation or sublimation, or may be supplied to the inside of the vacuum chamber together with a predetermined carrier gas, for example, a nitrogen (N2) gas, an argon (Ar) gas, a helium (He) gas, and/or a hydrogen (H2) gas. Alternatively, the silicon precursor 32a may be evaporated or sublimated in the vacuum chamber to be in a gaseous state.

Although not shown in the drawings, after the silicon precursor 32a is introduced into the vacuum chamber, a purge process of supplying a purge gas for removing the excess silicon precursor and the carrier gas not adsorbed on the substrate from the vacuum chamber to the vacuum chamber may be additionally performed. The purge gas may be an inert gas such as nitrogen gas or argon gas. If the carrier gas in the step S2 and the purge gas in the purge step are the same inert gas, a purge process may be performed only when the supply of the silicon precursor is stopped in a state in which the carrier gas is supplied to the vacuum chamber without adding a means for supplying only the purge gas. As a result of the step S2 and the purge process, as shown in FIG. 2b, a single layer of the silicon precursor 32a, i.e. a monolayer of an aminosilane-based gas, is formed only on the silicon oxide layer 22.

Subsequently, referring to FIGS. 1 and 2c, an oxidant gas is supplied into the vacuum chamber (S3). An ozone (O3) gas, an oxygen (O2) gas, or the like may be used as the oxidant gas. Alternatively, according to the embodiment, another gas containing oxygen as the oxidant gas, for example, a mixed gas of oxygen (O2)/hydrogen (H2), water vapor (H2O), and the like may be used. The oxidant gas supplied into the vacuum chamber may be bonded to silicon of an aminosilane-based gas adsorbed on the silicon oxide layer 22. It is preferable that the oxygen gas or the oxygen-containing gas is not in a plasma state, and when oxygen gas in a plasma state is used, it is difficult to secure a selectivity with respect to the titanium nitride layer because reactivity is too large.

As described above, when the oxidant gas is supplied, the silicon oxide layer 22 is additionally formed on the silicon oxide layer 22 by reacting with silicon of the aminosilane precursor 32a adsorbed on the silicon oxide layer 22. On the other hand, the silicon oxide layer 32 is not formed on the titanium nitride layer 24 on which the aminosilane precursor 32a is not adsorbed.

Furthermore, although not shown in the drawings, a purge gas is supplied to the inside of the vacuum chamber to exhaust the remaining oxidant gas, reaction by-products, or the like to the outside of the vacuum chamber. Accordingly, one cycle of the ALD process for the deposition of the optional silicon oxide layer 32 is completed.

Subsequently, the ALD process cycle including the steps S2 and S3 is repeated a predetermined number of times until the silicon oxide layer 32 having a desired thickness is formed on the silicon oxide layer 22. In this case, as the number of iterations of the cycle increases, a silicon oxide layer is additionally formed on the silicon oxide layer 22, whereas either the silicon oxide layer 32 may be not formed on the titanium nitride layer 24 at all, or, a silicon oxide layer (not shown) may be formed with a predetermined thickness (e.g., a thickness smaller than that formed on the silicon oxide layer 22). However, in the latter case, a portion of an upper portion of the silicon oxide layer 32 deposited on the silicon oxide layer 22 and a silicon oxide layer deposited on the titanium nitride layer 24 are simultaneously removed using a predetermined etching process such as an atomic layer etching (ALE) method. Finally, the silicon oxide layer 32 having a desired thickness may remain only on the silicon oxide layer 22.

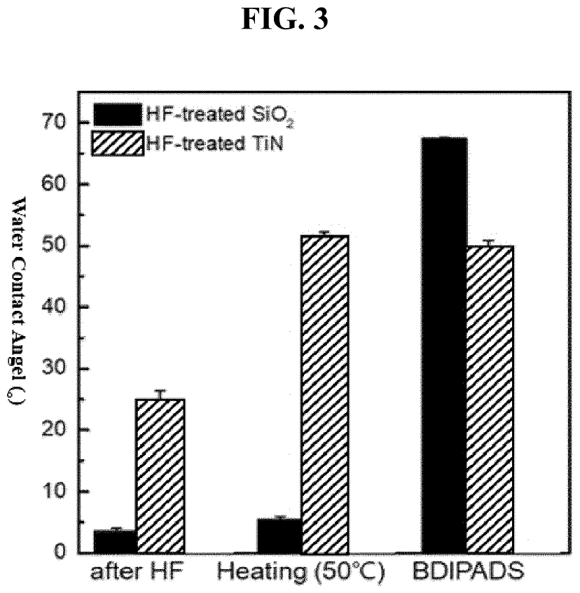

FIG. 3 is a graph showing a result of measuring a water contact angle (WCA) with respect to a material layer on a substrate on which a predetermined treatment is performed. The measurement of the water contact angle is intended to identify the hydrophilic property of the corresponding material layer, and thus it is possible to predict how well the aminosilane-based compound can be adsorbed on the corresponding material layer.

FIG. 3 shows water contact angles measured with respect to BDIPADS, after performing a process of heating a substrate at 50° C. after pretreatment with a hydrogen fluoride (HF) solution for each of a silicon oxide layer and a titanium nitride layer (after HF), and then adsorbing a single layer of a BDIPADS stock as in step S2 of FIG. 1. The adsorption process of BDIPADS was performed at a process temperature of 50° C. and for an exposure time of 2 seconds corresponding to one ALD cycle.

Referring to FIG. 3, in the case of the silicon oxide layer, after the substrate is simply treated with HF, the water contact angle was about 4°, but when the silicon oxide layer was heated to 50° C. the water contact angle was slightly increased to about 7°, whereas after the BDIPADS adsorption process was performed, the water contact angle was increased to about 65°. Accordingly, it can be seen that, after the BDIPADS adsorption process is performed, a single layer of BDIPADS SCF is actually formed on the silicon oxide layer. On the other hand, in the case of the titanium nitride layer, after the substrate was simply treated with HF, the water contact angle was about 25°, but after the BDIPADS adsorption process was performed, the water contact angle increased to about 50°, which is almost the same as the water contact angle observed when the substrate was heated to 50° C. This indicates that even after the BDIPADS adsorption process, a monolayer of BDIPADS is hardly formed on the titanium nitride layer.

In summary, when an aminosilane-based compound such as BDIPADS is contacted to a substrate in which both the silicon oxide layer and the titanium nitride layer are exposed, the aminosilane-based compound is adsorbed on the silicon oxide layer, but the aminosilane-based compound is not adsorbed on the titanium nitride layer or the adsorption rate is remarkably low.

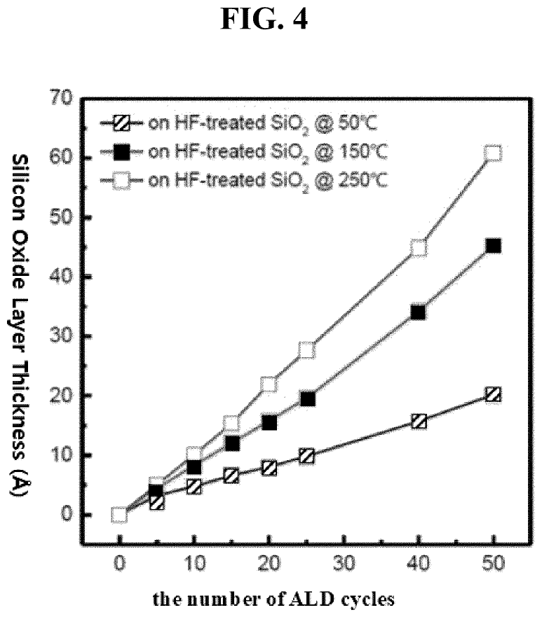

FIG. 4 is a graph showing the deposition rate of the silicon oxide layer 32 according to the temperature of the ALD process, that is, the temperature inside the vacuum chamber. The experimental result of FIG. 4 is a case in which the silicon oxide layer 32 is deposited by an ALD process consisting of two seconds of BDIPADS imide precursor exposure, 30 seconds of nitrogen purge, 5 seconds of ozone oxidant exposure, and 60 seconds of nitrogen purge, wherein the temperature of the ALD process is changed to 50° C., 150° C., and 250° C., respectively. Referring to FIG. 4, it can be seen that the deposition rate of the silicon oxide layer 32 increases as the process temperature rises, it is deposited at a deposition rate of about 0.5 Å to about 1 Å per cycle, and when the number of cycles is more than 50 times, the deposition rate is greater than that of the earlier cycles. According to the graph, it can be seen that at least 50 ALD cycles should be performed to deposit the silicon oxide layer 32 having a thickness of about 30 Å to 100 Å.

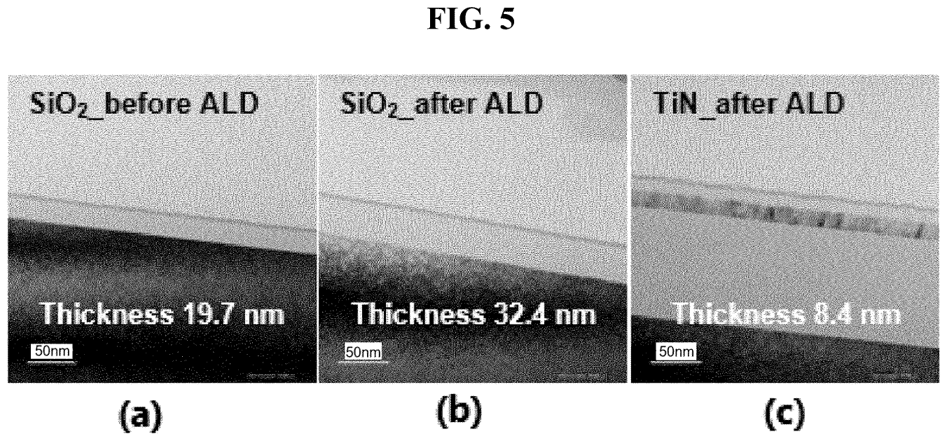

FIGS. 5 to 7 are an ion-milling transmission electron microscope (TEM) photograph showing a result of performing selective deposition of a silicon oxide layer using an ALD process according to an embodiment of the present invention described above, wherein the temperature inside the vacuum chamber is 200° C., 100° C., and 150° C., respectively. While process conditions other than temperature are all the same, the substrate was cleaned (pre-treated) with 0.5% hydrofluoric acid (HF) solution for 30 seconds, and each cycle of the ALD quenching process was composed of a BDIPADS imide precursor supply of 2 seconds, a nitrogen purge of 30 seconds, an ozone oxidant supply of 5 seconds, and a nitrogen purge of 60 seconds to perform deposition.

In FIGS. 5 to 7, a drawing (a) is an ion milling TEM photograph of a silicon oxide layer (SiO2_before ALD) before an ALD process is performed, a drawing (b) is an ion milling TEM photograph of a silicon oxide layer (SiO2_before ALD) after an ALD process is performed, and a drawing (c) is an ion milling TEM photograph of a titanium nitride layer (TiN_after ALD) after an ALD process is performed.

Referring to FIG. 5, as a result of performing an ALD process at 200° C. for 120 cycles, a silicon oxide layer having a thickness of 12.7 nm (30.4 nm-19.7 nm) was deposited on the silicon oxide layer, and a silicon oxide layer having a thickness of 8.4 nm was deposited on the titanium nitride layer. Therefore, at a process temperature of 200° C., a selective ratio is provided such that a silicon oxide layer of 4.3 nm is more deposited on the silicon oxide layer, compared to the titanium nitride layer.

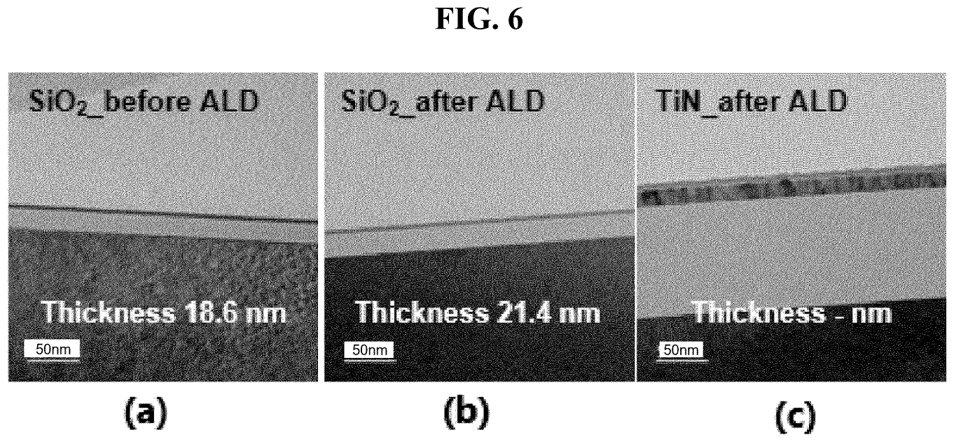

Referring to FIG. 6, as a result of performing an ALD process at 100° C. for 60 cycles, a silicon oxide layer having a thickness of 2.8 nm (21.4 nm-18.6 nm) was deposited on the silicon oxide layer, and a silicon oxide layer was not deposited on the titanium nitride layer. Therefore, at a process temperature of 100° C., a selective ratio is provided such that a silicon oxide layer of 2.8 nm is more deposited on the silicon oxide layer, compared to the titanium nitride layer.

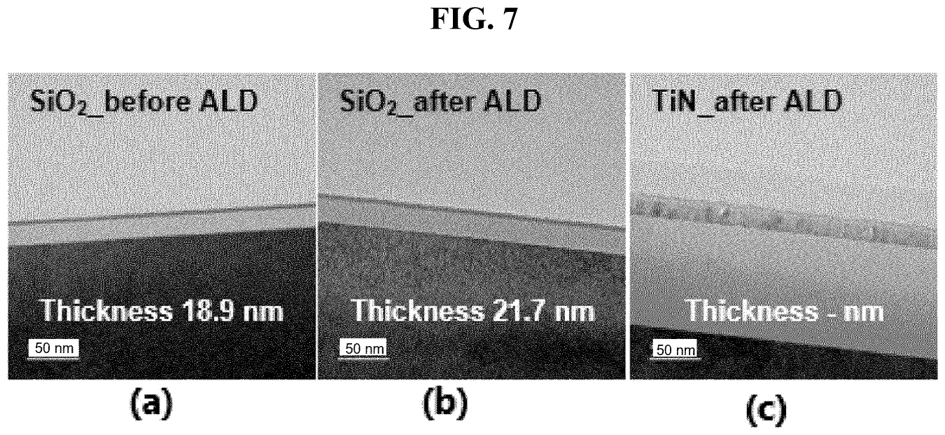

Referring to FIG. 7, as a result of performing an ALD process at 150° C. for 35 cycles, a silicon oxide layer having a thickness of 2.8 nm (21.7 nm to 18.9 nm) was deposited on the silicon oxide layer, and a silicon oxide layer was not deposited on the titanium nitride layer. Therefore, at a process temperature of 150° C., a selective ratio is provided such that the silicon oxide layer having a thickness of 2.8 nm is more deposited on the silicon oxide layer, compared to the titanium nitride layer.

Although not shown in the drawings, as a result of performing the ALD process at 50° C. a silicon oxide layer having a thickness of 4.5 nm was deposited on the silicon oxide layer, whereas a silicon oxide layer having a thickness of 2.2 nm was deposited on the titanium nitride layer. Therefore, at a process temperature of 50° C., a selective ratio is provided such that a silicon oxide layer of 2.3 nm is more deposited on the silicon oxide layer compared to the titanium nitride layer.

Although the present invention has been described in detail with reference to the preferred embodiments, the present invention is not limited to the above-described embodiment, and various modifications may be made by those skilled in the art within the scope of the technical idea of the present disclosure.

The present invention may be applied to a semiconductor element manufacturing process.

1. A selective deposition method of a silicon oxide layer, comprising the steps of:
preparing a substrate in which a first silicon oxide layer (SiO2) and a titanium nitride layer (TiN) are exposed in a vacuum chamber;
a first supply step of supplying an aminosilane-based gas into the vacuum chamber so as to be adsorbed on at least the first silicon oxide layer; and
a second supply step of supplying an oxidizing agent into the vacuum chamber so as to react with the adsorbed aminosilane-based gas,
wherein the first supply step and the second supply step are repeatedly performed a plurality of times to form a second silicon oxide layer having a predetermined thickness on the first silicon oxide layer.

2. The selective deposition method of claim 1, wherein the aminosilane-based gas includes one or more of BDIPADS, DIPAS, and 3DMAS.

3. The selective deposition method of claim 1, wherein the oxidizing agent may include one or more selected from ozone gas, oxygen gas, and oxygen/hydrogen mixed gas.

4. The selective deposition method of claim 1, further comprising a pre-treatment step of cleaning the substrate with a hydrofluoric acid solution prior to the first supply step.

5. The selective deposition method of claim 1, wherein in the first supplying step and the second supplying step, the temperature of the vacuum chamber is set to 100 to 200° C.
